(19) United States
(12) Patent Application Publication
(10) Pub. No.: US 2008/0035315 A1
(43) Pub. Date: Feb. 14, 2008

(54) Cooling system with miniature fans for circuit board devices

(75) Inventor: Tai-Sheng (Andrew) Han, Fullerton, CA (US)

Correspondence Address: BUCHANAN, INGERSOLL & ROONEY PC, POST OFFICE BOX 1404, ALEXANDRIA, VA, 22313-1404, US

(73) Assignee: EVGA Corporation, Brea, CA (US)

(21) Appl. No.: 11/820,279

(22) Filed: Jun. 19, 2007

Related U.S. Application Data
(63) Continuation-in-part of application No. 11/314,873, filed on Dec. 20, 2005.
(60) Provisional application No. 60/692,594, filed on Jun. 22, 2005.
(60) Provisional application No. 60/639,052, filed on Dec. 23, 2004.

(51) Int. Cl. H01L 23/467

(52) U.S. Cl. 165/121

(57) ABSTRACT

Devices for removing heat from electronic components. A device includes a heat sink for attachment to an electronic component and multiple miniature fans. Each miniature fan includes an elongated, generally tubular outer housing member adapted to receive end closure plugs or caps at each end, a miniature electric motor mounted within one of the end caps, and a generally cylindrical shaped rotor/impeller disposed within the tubular housing and extending along the length thereof between the end caps, one end thereof being coupled to the motor. The housing member is provided with openings that extend longitudinally along one side thereof to provide an entrance port, and openings that extend along another side to provide an outlet or exit port. With the exception of the motor, all other parts can be made of an injection molded plastic, metal, or a combination of plastic and metal.

### CROSS REFERENCE TO RELATED APPLICATIONS

This application is a continuation-in-part of U.S. patent application Ser. No. 11/314,873, entitled “Miniature Fan for High Energy Consuming Circuit Board Devices” by Han, Tai Sheng, filed on Dec. 20, 2005, which is hereby incorporated by reference in its entirety.

### BACKGROUND OF THE INVENTION

It is well known that some types of electronic circuit card or board devices consume relatively large amounts of electrical power and generate substantial amounts of thermal energy (heat) that must be removed if the device is to continue to operate as intended. For example, in modern computer products, heat dissipation is a problem that unless properly dealt with can cause the computer to malfunction or become inoperative due to overheating. This is of particular importance in the case of high performance computer devices used to rapidly process graphics and game technology. Thus, heat dissipation has become a critical issue that vendors have spent large effort to resolve. In PC units used for graphics and games, add-on units generally referred to as “graphics cards” or “VGA cards” are often installed in the computers. Such cards include a separate processor, called a GPU, one or more memory chips, and other required circuitry, all mounted to an ancillary circuit board having an edge connector that is adapted to plug into an available slot in the mother board of the principal computing device. Such cards often have extremely large computing power and, as a consequence, generate substantial heat that, if not dissipated, will adversely affect operation of the graphics card and/or PC.

Heretofore, various approaches have been tried to dissipate or otherwise remove heat from the thermal energy generating processor units and normally include some type of thermal mass capable of sinking the heat generated, as well as some type of fan for blowing air across the sink and active components.

Conventional heat dissipation heat sinks usually include a thick metal plate having a plurality of metal fins located on one side thereof to disperse the heat over a large surface area. Some sinking applications do not need additional airflow to disperse heat, and simply dissipate the energy by, in effect, increasing the radiation area of the heat generating unit. The commonly used basic heat sink is thus passive and cools by convection. However, while the simple heat sink can increase the radiation area, heat energy still has to be discharged by airflow into the surrounding area.

Means for circulating cooling air by use of a fan has been the most commonly used method for removing thermal energy from a heat source and its associated sinking device. In the usual case, outside air is taken into an apertured heat dissipation device attached to a heat source, passed through the interior of the heat dissipation device, and then discharged to the outside of the device. However, since in most applications the fan or air induction device is a simple multi-bladed rotary fan, or a short axis squirrel cage type blower, itself having a reduced thickness, cooling air does not always flow smoothly through the interior of the heat dissipation device. And since the non-smooth flow of cooling air decreases the cooling efficiency of a radiation device, heat from the thermal source cannot be effectively gathered and carried to the outside. In addition, typical squirrel cage type fans are noisy.

It is known that cooling performance can be improved by an increase in the flow rate of cooling air. However, since this measure typically requires an increase in the size of a fan or a decrease in the cross section of the flow path, it is problematic since the overall thickness of the heat radiation device usually cannot be increased and the dimensions of the data processing apparatus cannot be decreased. Furthermore, from a practical standpoint, space for accommodating a larger fan is not available in a thin heat radiation device, and the thickness of the data processing apparatus cannot be reduced.

There is thus a need for a new type of fan or blower that can be readily attached to a card or heat sink without requiring extra flow directing means for interfacing the fan effluent to the heat sink or device to be cooled.

High performance notebook computers are extremely compact devices that require high performance central processing units (CPUs), and as do the graphics processors, such high performance electronic components also generate a significant amount of heat during operation. Unless removed, such heat also degrades the processing speed and/or performance of the device. For this reason, high temperature, heat generating CPUs are normally provided with some type of cooling means designed in response to the temperature generated by the component. Specifically, when the heat generating unit generates low heat, it can simply be air-cooled using a heat sink or a heat pipe. But when the heat generating unit generates a significant amount of heat, it must be forcibly cooled using a fan, or perhaps both an active cooler, such as a Peltier device, and a fan. For example, in today's high performance notebook PCs, it is very difficult to simply air-cool a CPU that generates a large amount of heat. Accordingly, almost all high-performance notebook PCs are forcibly cooled using an active cooling system including a fan and a custom engineered heat sink assembly

However, as laptop computers and other consumer, commercial, and military electronics, are continuously reduced in size, the space available for mounting a conventional multi-blade fan or squirrel cage type blower is also reduced. There is thus a need for a smaller and improved air moving mechanism, which can be added to a standard graphics card to efficiently remove thermal energy generated thereby.

### SUMMARY OF THE INVENTION

According to one embodiment of the present invention, a means for removing heat from electronic components includes: a heat sink for attachment to an electronic component, adapted to form at least one flow channel, and including means for directing a stream of heat removing fluid over at least one surface thereof; and a plurality of fans for attachment to the heat sink and adapted to generate stream of heat removing fluid through the channel. Each fan includes: an elongated housing open along its length and at both ends to form a rotor receiving chamber, the housing having an inlet port formed in one side thereof and an outlet port formed in another side thereof; an elongated rotor disposed within the chamber and rotatable about a longitudinal axis thereof, the rotor having a plurality of impeller components extending along its length; a first end cap affixed to the housing and closing one end of the chamber, and a second end cap affixed to the housing and closing an opposite end thereof; a motor disposed at the one end of the chamber and adapted to cause the rotor to rotate about the longitudinal axis whereby ambient fluid is drawn through the inlet port into the chamber by said impeller components and expelled therefrom through the outlet port; and means for mounting the fan to the heat sink.

### IN THE DRAWING

FIG. 1 is a perspective view illustrating miniature fans in accordance with the present invention affixed to two sides of a flow directing heat sink mounted to a graphics card assembly or the like;

FIG. 2 is an enlarged perspective view more clearly illustrating the exterior details of the miniature fan of FIG. 1 showing the inlet opening side thereof;

FIG. 3 is an enlarged perspective view more clearly illustrating the exterior details of the miniature fan of FIG. 1 showing the outlet opening side thereof;

FIG. 4 is an exploded perspective view illustrating the principal component parts of the miniature fan of FIG. 1, the main housing member part thereof being broken to show the inlet opening in the remote side thereof;

FIG. 5 is a perspective view showing the housing member and end caps broken along a plane passing through the longitudinal axis of the impeller to illustrate certain interior details of the miniature fan of FIG. 1;

FIG. 6 is a stylized transverse sectional view schematically showing the air flow characteristics of the miniature fan of FIG. 1;

FIGS. 7-12 are schematic perspective views of various embodiments of a heat sink that might be used in a graphic card assembly or the like in accordance with the present invention;

FIG. 13 is a schematic cross sectional view of the heat sink of FIG. 12, taken along the line XIII-XIII;

FIG. 14 is a schematic perspective view of another embodiment of a heat sink that might be used in a graphic card assembly or the like in accordance with the present invention;

FIG. 15 is a schematic cross sectional view of the heat sink of FIG. 14, taken along the line XV-XV;

FIG. 16 is a schematic perspective view of yet another embodiment of a heat sink that might be used in a graphic card assembly or the like in accordance with the present invention;

FIG. 17 is a schematic cross sectional view of the heat sink of FIG. 16, taken along the line XVII-XVII;

FIG. 18 is a schematic perspective view of still another embodiment of a heat sink that might be used in a graphic card assembly or the like in accordance with the present invention;

FIG. 19 is a schematic cross sectional view of the heat sink of FIG. 18, taken along the line XIX-XIX; and

FIG. 20 is a schematic perspective view of a further embodiment of a heat sink that might be used in a graphic card assembly or the like in accordance with the present invention.

### DETAILED DESCRIPTION OF PREFERRED EMBODIMENTS

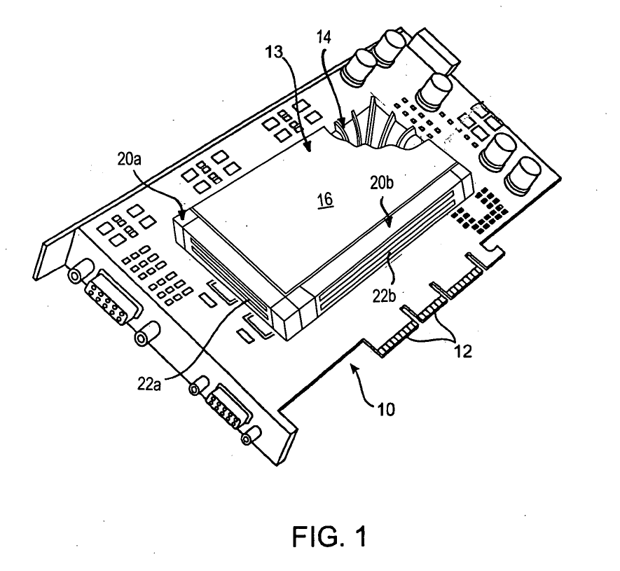

Referring now to FIG. 1 of the drawing there is shown at 10 a typical example of a graphics card of the type that might be installed in a PC by inserting the edge connectors 12 into an available slot on the motherboard (not shown). Shown mounted to the top of the card 10 is a heat sink assembly (or, shortly heat sink) 13 that might include a metal bottom plate having a plurality of upstanding ribs formed integral therewith as depicted at 14. Affixed to the top of the ribs is a metal upper plate 16 having its upper left corner broken away to reveal the ribbed lower part 14. Note that the bottom and top plates are separated by the ribs and that the ribs are generally curved strips and arranged to fan out from the central portion of the assembly 13. The ribs define a plurality of air flow passageways extending along the heat sink towards the space where the air flow is discharged to.

Affixed to the foreground and side edges of heat sink 13 are embodiments of fans or blower devices 20a, 20b in accordance with the present invention. Each of the devices 20a, 20b is generally in the form of an elongated right rectangular structure having its long dimension extending along the rightmost or foreground edge of card 13. Fans 20a, 20b are affixed to card 13 by any suitable means, such as tabs and screws or bolts (not shown), an adhesive, or tack welds. A single, pair or other plurality of inlet slots 22a (or 22b) is/are provided on the front side face of each device. Air is drawn in through these slots for expulsion through one or more exit slots (not shown) on the back side thereof for introduction by the fans into the heat sink 13.

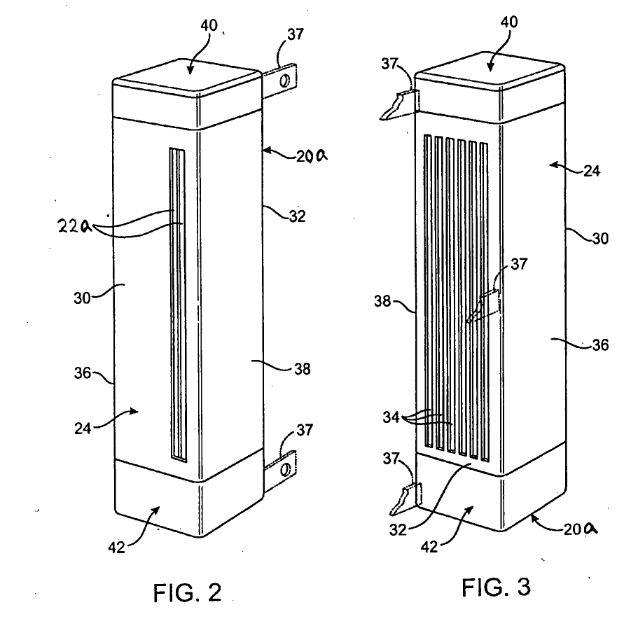

As the fans 20a, 20b have the same structure, only one fan 20a is described hereinafter. The exterior construction of the fan 20a is shown in enlarged detail in FIGS. 2 and 3 wherein the front face including the air flow inlet slots 22a is depicted in FIG. 2, and the rear face, including the plurality of air flow outlet slots 34, is depicted in FIG. 3. As shown in these figures, the exterior housing of fan 20 is formed by a generally tubular housing member 24 having a rectangular (square) transverse cross section defined by a first pair of parallel opposing front and rear walls 30 and 32, and a second pair of opposing parallel side walls 36 and 38. The otherwise open ends of the tubular housing member 24 are closed by a pair of end caps 40 and 42 to form a rotor receiving internal chamber (not shown). Alternatively, the cross section could be formed in other geometric shapes including oval or partially oval, or of any other suitable transverse sectional configuration capable of cooperating with an impeller and inlet and outlet openings to form a blower device. The device can be made in almost any desired size and length. For example, in one small size embodiment, the device has external dimensions of 1.2×1.2×5 centimeters.

As will be further explained below, the inlet slot or slots 22a are arrayed or positioned on one side of the front wall 30 to extend across substantially the entire longitudinal length of the housing member 24, while the outlet slot or slots 34 are arrayed or positioned on the opposite side of the housing member 24 and occupy a larger area of the rear face 32. Preferably, the inlet openings or slots 22a are disposed on one side of a plane (not shown) intersecting the housing 24 normal to front wall 30, and passing through the longitudinal axis of the device. The outlet openings or slots 34 are symmetrically positioned on both sides of the same plane as it extends through and out of the opposite side of the device. Hereinafter, the term inlet port is used interchangeably with inlet slots 22a and the term outlet port is used interchangeably with outlet slots 34. In this embodiment, the end caps 40 and 42 are of slightly different size, with the cap 40 serving as a bearing support member, and the cap 42 serving as a drive motor housing as well as bearing support. Suitable flanges, tabs or other means such as those suggested by the dashed lines 37 in FIGS. 2 and 3, may be provided for fastening the fan device to a PC board, heat sink or other supporting structure. Such fastening means may be affixed to or molded integral with the tubular housing 24 and/or the end caps 40, 42. Alternatively, the fan could be attached to a supporting structure by one or more straps (not shown).

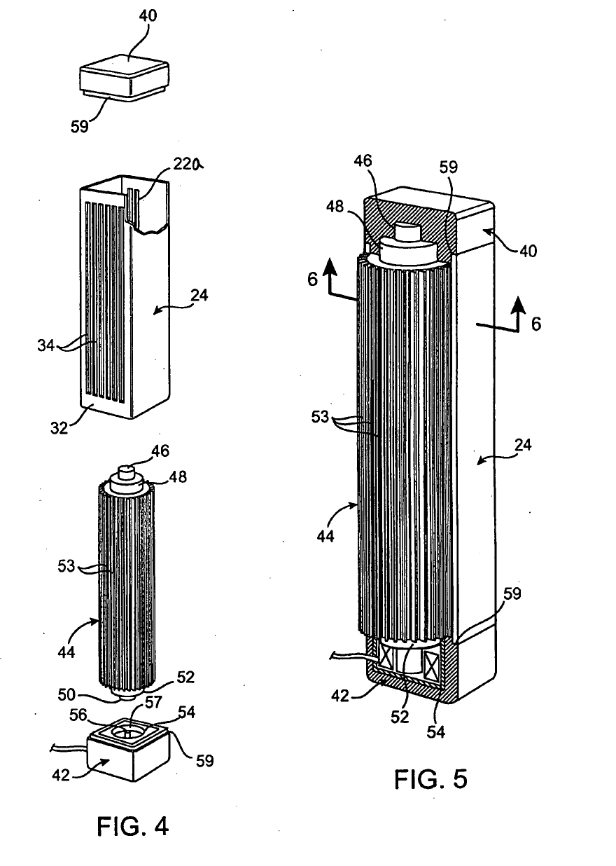

Turning now to FIG. 4, the fan device is shown with the end caps 40 and 42 exploded axially outwardly from their mating engagement with the tubular housing 24. Also shown removed axially from the tubular housing 24 is an impeller or rotor 44 having a supporting shaft extending axially from each end at 46 and 50. A suitable annular bearing member 48 is coaxially disposed on the upper end 46 as depicted. A similar bearing member 52 is provided on shaft end 50 at the opposite end of rotor 44. Although not shown in this figure, the end cap 40 includes a receptacle for receiving the bearing 48 and shaft end 46 such that the end 46 of rotor 44 is journalled to end cap 40.

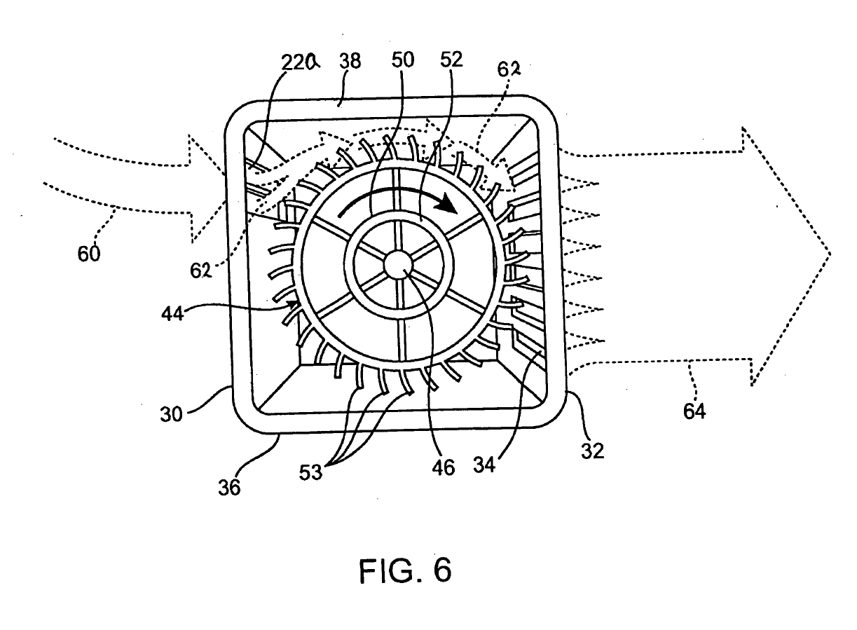

As depicted in this figure, the rotor 44 is formed of an elongated, solid or hollow, cylindrically shaped body having a plurality of elongated vanes 53 extending along the length thereof. The vanes 53 may be parallel and continuous or segmented along the length of the rotor, and may be straight, helical or serpentine relative to the axis of the rotor. Furthermore, the planes of the vanes may extend radially, at an angle to radial (as depicted in FIG. 6), be segmented and cup-shaped, or have any other suitable configuration designed to move fluid from the entrance side of the housing to the other side for exit.

At the bottom of FIG. 4, the lower end cap 42 is shown to include a receptacle 57 for receiving the bearing 52 and shaft end 50 such that the end 50 of rotor 44 is journalled to end cap 42. End cap 42 also has a pocket in which a small electric motor 54 is nested. The motor may be AC or DC, but is typically a DC motor operated at a voltage of between 4-24 volts conveniently available from a computer power supply. Motor 54 is provided with a drive shaft 56 having a square shaped, hex-shaped or other suitable cross section that can be mating engaged within a similarly configured female socket 56 (FIG. 6) formed in the end of shaft 50 so as to provide direct drive to rotor 44.

The four parts shown separate in FIG. 4 are assembled by collapsing the several components axially, with rotor 44 moving downwardly to engage the bearing 52 and motor 54, and housing 24 slipping over rotor 44 so that its lower end engages and seats within the shoulder 59 in lower cap 42. The assembly is completed by mating the shaft end 46 and bearing 48 with the corresponding receptacles (not shown) formed in the lower side of end cap 40, and seating the upper end of housing 24 in the shoulder 59 formed around the lower perimeter of the upper end cap 40. The caps 40 and 42 may be designed to snap fittingly engage the ends of member 24 or they may be retained by the use of glue or epoxy or the like. The assembled engagement is shown in FIG. 5, wherein the housing 24, end caps 40 and 42, and motor 54 are, for clarity, shown split along the longitudinal axis of the fan to illustrate the assembled configuration of the several previously described component parts.

FIG. 6 is a stylized, transverse sectional view taken in the plane 6-6 of FIG. 5 and shows how the vanes 53 “drag” or “draw” ambient air (represented by the dashed lines 60) in through inlet slots 22a, “carry” it across the lower portion of the housing 24 (as suggested by the dashed lines 62), and then centrifugally “throw” it out through the outlet slots 34 (as suggested by the dashed lines 64). It is believed that with the rotor rotating about its longitudinal axis, the vanes 53 in effect scoop the ambient air at the low pressure inlet slots 22 and cause it to move with the rotor around the inside of the housing. As the moving air experiences centrifugal acceleration tangentially and radially outwardly relative to the axis of rotation of the rotor, it also experiences an increase in pressure and momentum that causes it to exit the housing via the outlet slots 34. As a consequence, the device acts to draw air into one side thereof and blow it out the other side thereby functioning as a fan.

As suggested above, with the exception of the motor 54, all of the several device components can be made using small, structurally simple, injection molded metal, plastic or ceramic parts that can be snap-fit or glued together during assembly to form elongated fluid pumping devices of various sizes having substantial utility for the particular application described above as well as other applications having similar requirements. Furthermore, whereas the “pumping” efficiency of the fan device could perhaps be improved by “streamlining” the interior walls of the housing 30 to eliminate corners and enhance laminar flow within the housing, such streamlining is not deemed necessary to provide a device capable of creating an air flow useful for the suggested applications.

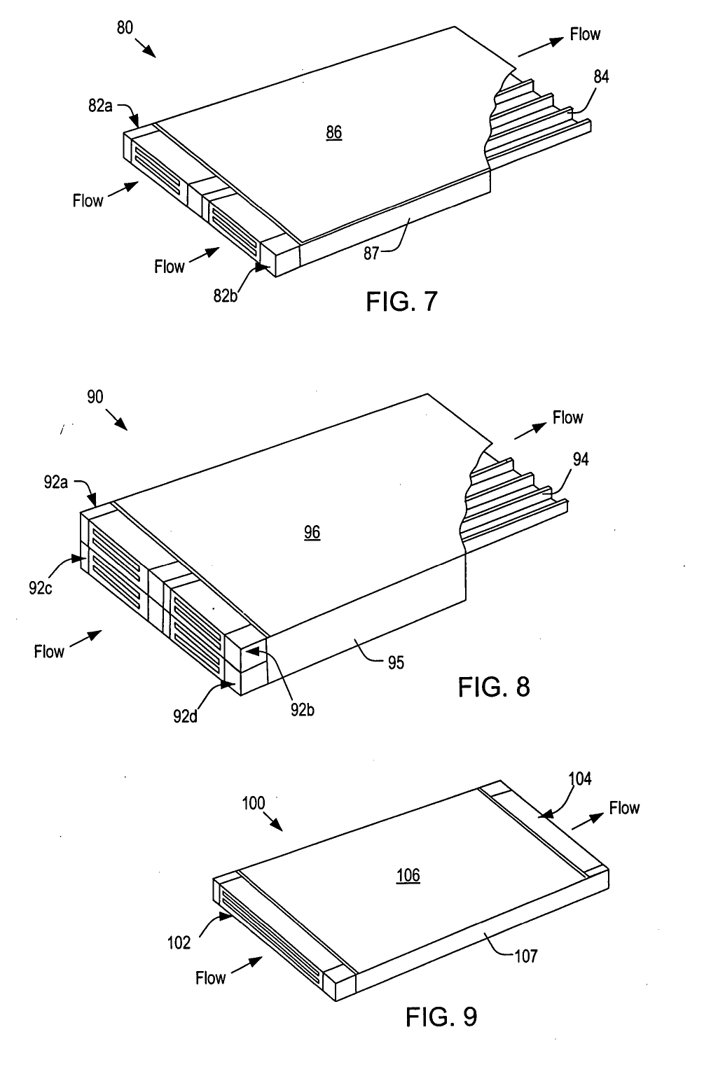

FIG. 7 is a schematic perspective view of another embodiment of a heat sink 80 of the type to be used in a graphic card assembly or the like in accordance with the present invention. For the purpose of illustration, the metal upper plate 86 is partially broken away to reveal the ribs 84 affixed thereto. The fans 82a, 82b have the similar structure and operational mechanisms as the fan 22a depicted in FIGS. 1-6. As depicted, the heat sink 80 is similar to the assembly 16 in FIG. 1, with the differences that two fans 82a, 82b are affixed to the foreground edge of heat sink in series (i.e., the top end cap of the fan 82b is in contact with the bottom end cap of the fan 82a) and the ribs 84 are disposed in a parallel array. Two side plates 87 and the top upper plate 86 form a channel and the fans 82a, 82b direct ambient air into one end of the channel. The ambient air directed by the fans 82a, 82b flows through the channel and exits at the opposite end of the channel. As a variation, two or more fans may be affixed to the rightmost edge of a heat sink with ribs extending toward the leftmost edge of the heat sink such that the air is drawn in by the fans at the rightmost edge of the heat sink and discharged at the left side of the heat sink. It is noted that only two fans are shown in FIG. 7, even though other suitable number of fans may be affixed in series to the foreground or rightmost side of the heat sink. Likewise, the heat sink 16 in FIG. 1 may have other suitable number of fans affixed to the foreground and rightmost sides of the heat sink.

FIG. 8 is a schematic perspective view of yet another embodiment of a heat sink 90 of the type to be used in a graphic card assembly or the like in accordance with the present invention. As in FIG. 7, for the purpose of illustration, the metal upper plate 96 is partially broken away to reveal the ribs 84 affixed thereto. The four fans 92a-92d have the similar structure and operational mechanisms as the fan 22a depicted in FIGS. 1-6. As depicted, the heat sink 90 is similar to the heat sink 80 in FIG. 7, with the difference that four fans 92a-92d are affixed to the foreground edge of the heat sink in a two-dimensional array. The upper plate 96 and two side plates 95 form a channel, wherein the four fans 92a-92d are disposed at one end of the channel and generate flow that proceeds toward the opposite end of the channel. The outlet ports of the four fans 92a-92d face the opposite end of the channel (or, equivalently, the background edge of the heat sink 90). As a variation, the four fans disposed in a two-dimensional array may be affixed to the rightmost edge of a heat sink with ribs extending toward the leftmost edge of the heat sink such that the air is drawn in by the fans at the rightmost edge of the heat sink and discharged at the left side of the heat sink.

FIG. 9 is a schematic perspective view of still another embodiment of a heat sink 100 of the type to be used in a graphic card assembly or the like in accordance with the present invention. The two fans 102, 104 have the similar structure and operational mechanisms as the fan 22a depicted in FIGS. 1-6 and respectively disposed at the foreground and background edges of the heat sink 100. The outlet port of the fan 102 faces the inlet port of the fan 104 such that the flow drawn in by the fan 102 is discharged by the fan 104. In this embodiment, the two fans are respectively disposed at the two ends of the channel formed by the upper plate 106 and two side plates 107. It is noted that the heat sink may include ribs affixed to the upper plate 106 in a parallel array. As a variation, the two fans may be affixed to the rightmost and leftmost edges of the heat sink such that the air is drawn in by the fan at the rightmost edge of the sink and discharged by the fan at the leftmost edge of the sink.

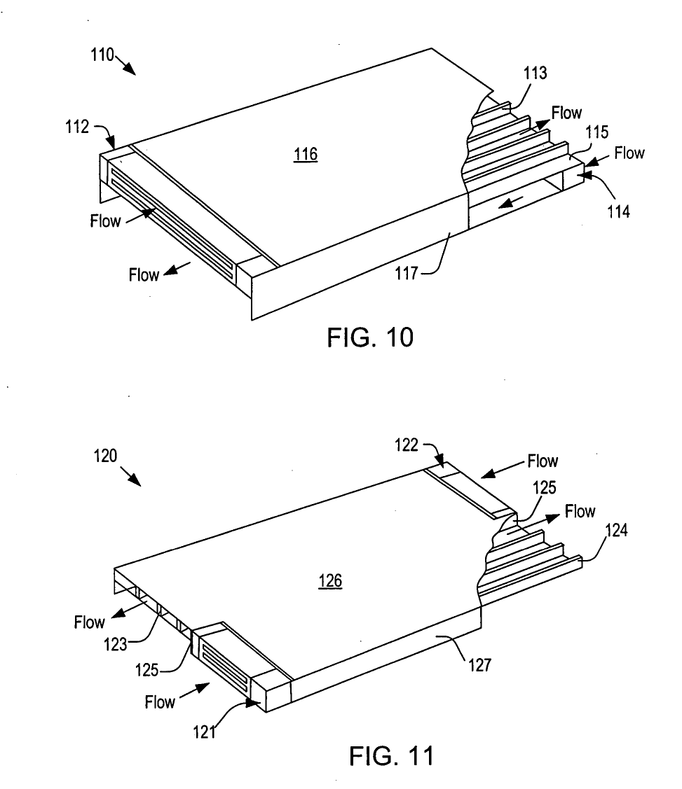

FIG. 10 is a schematic perspective view of a further embodiment of a heat sink 110 of the type to be used in a graphic card assembly or the like in accordance with the present invention. For the purpose of illustration, the metal upper plate 116 is partially broken away to reveal the ribs 113 affixed thereto. The channel formed by the upper plate 116 and side plates 117 is separated into upper and lower channels by the middle plate 115 affixed to the ribs 113. The two fans 112, 114 have the similar structure and operational mechanisms as the fan 22a depicted in FIGS. 1-6. The upper fan 112 is disposed at one end of the upper channel, while the lower fan 114 is disposed at the opposite end of the lower channel. The upper flow generated by the upper fan 112 proceeds through the upper channel in a direction opposite to the lower flow generated by the lower fan 114.

As a variation, the two fans may be respectively affixed to the upper portion of the rightmost edge and lower portion of the leftmost edges of the heat sink with ribs extending in a direction substantially normal to the longitudinal axes of the fans. In this variation, a middle plate separates the channel into upper and lower channels such that the air drawn by the fan at the rightmost edge of the heat sink flows in the upper channel while the air drawn by the fan at the leftmost edge of the heat sink flows in the lower channel. Also, the flow in the upper channel proceeds in a direction opposite to the flow in the lower channel.

FIG. 11 is a schematic perspective view of another further embodiment of a heat sink 120 of the type to be used in a graphic card assembly or the like in accordance with the present invention. For the purpose of illustration, the metal upper plate 126 is partially broken away to reveal the ribs 124 affixed thereto. The channel formed by the upper plate 126 and side plates 127 is separated into right and left channels by the middle plate 125 affixed to the upper plate. Two fans 121, 122 have the similar structure and operational mechanisms as the fan 22a depicted in FIGS. 1-6. The fan 121 is disposed at one end of the right channel, while the fan 122 is disposed at the opposite end of the left channel. The flow generated by the fan 121 proceeds through the right channel in a direction opposite to the flow generated by the fan 122 in the left channel.

As a variation, a middle plate extends from the rightmost edge to the leftmost edge of the heat sink, dividing the channel into front and rear channels. In this variation, a first fan is disposed at the one end of the front channel while a second fan is disposed at the opposite end of the rear channel. The flow in the front channel proceeds in a direction opposite to the flow in the rear channel.

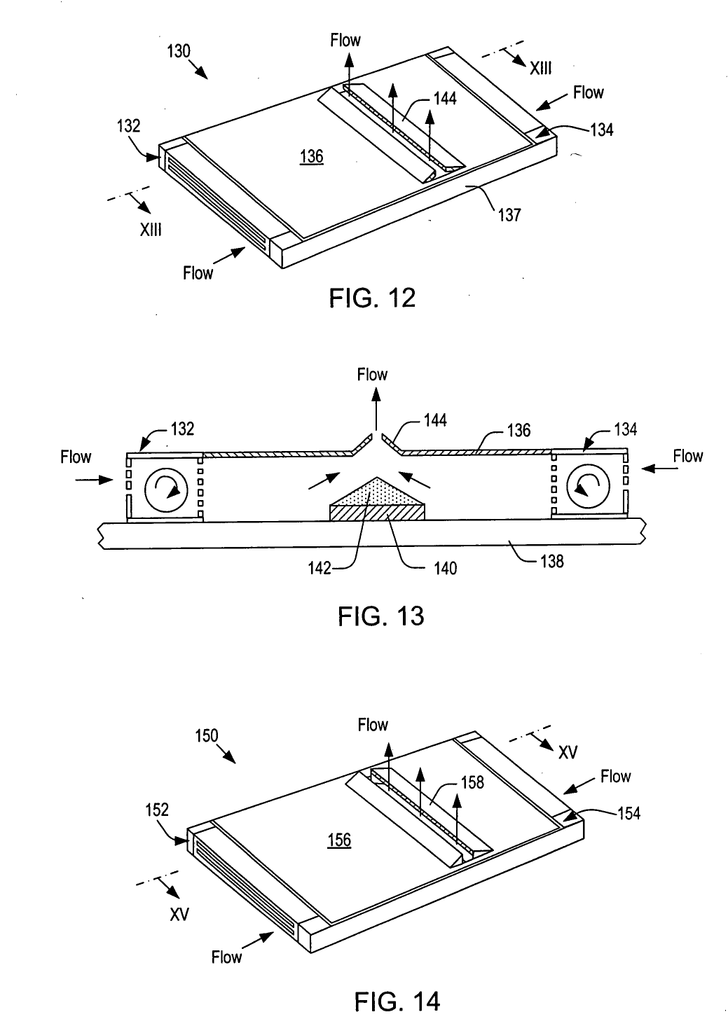

FIG. 12 is a schematic perspective view of another further embodiment of a heat sink 130 of the type to be used in a graphic card assembly or the like in accordance with the present invention. FIG. 13 is a schematic cross sectional view of the heat sink 130, taken along the line XIII-XIII. The heat sink 130 includes two fans 132, 134 that have the similar structure and operational mechanisms as the fan 22a depicted in FIGS. 1-6. As depicted in FIGS. 12-13, a first fan 132 is disposed at foreground edge of the heat sink, while a second fan 134 is disposed at the background edge of the heat sink. In this embodiment, the upper plate 136 and two side plates 137 form a flow channel. Ambient air is directed into the channel by the fans 132, 134 that are respectively disposed at the two ends of the channel and sent toward the center of the heat sink. The upper plate 136 includes an elongated exit port 144 through which the air is discharged. The exit port 144 extends transverse to the flow in the channel and, in one exemplary embodiment, may spans almost the entire width of the upper plate 136. The heat sink also includes a flow deflector 142 disposed in the heat sink to direct the air flow toward the nozzle 144. The flow deflector 142 may be mounted on a heat generating component 140, such as GPU, which is positioned on a graphic card assembly 138 or the like and disposed under the exit port 144. As a variation, the two fans may be affixed to the rightmost and leftmost edges of the heat sink and the exit port 144 extends substantially transverse to the flow in the channel.

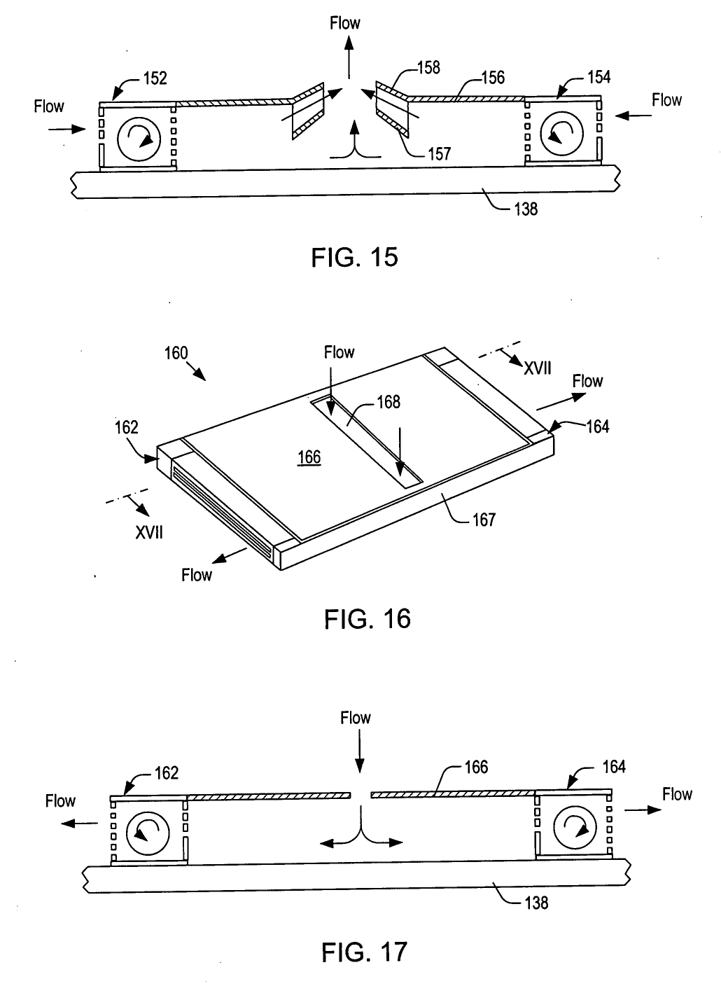

FIG. 14 is a schematic perspective view of another embodiment of a heat sink 150 of the type to be used in a graphic card assembly or the like in accordance with the present invention. FIG. 15 is a schematic cross sectional view of the heat sink 150, taken along the line XV-XV. As depicted, the heat sink 150 is similar to the heat sink 130 in FIGS. 12-13, with the difference that the heat sink 150 includes an elongated scoop or deflector 157 attached to the bottom surface of the upper plate 156 and positioned under the exit port 158. The deflector 157 includes a pair of elongated plates that are arranged in a spaced-apart relationship with the exit port 158 and direct the flow toward the exit port, aiding the ventilation of flow. As a variation, the two fans may be affixed to the rightmost and leftmost edges of the heat sink while the exit port and deflector extend substantially transverse to the flow in the channel.

FIG. 16 is a schematic perspective view of another embodiment of a heat sink 160 of the type to be used in a graphic card assembly or the like in accordance with the present invention. FIG. 17 is a schematic cross sectional view of the heat sink 160, taken along the line XVII-XVII. As depicted, the heat sink 160 is similar to the heat sink 130 in FIGS. 12-13, with the differences that the upper plate 166 includes an elongated opening or slit 168 formed therein and that the air drawn through the opening is discharged from the heat sink 160 by two fans 162, 164. The opening 168 extends transverse to the flow in the channel. In this embodiment, two fans 162, 164 are respectively disposed at the two ends of the channel formed by the upper plate 166 and two side plates 167 and direct ambient fluid into the channel through the opening 168. As a variation, the two fans may be affixed to the rightmost and leftmost edges of the heat sink and the opening 168 extends in a direction substantially parallel to the longitudinal axes of the fans.

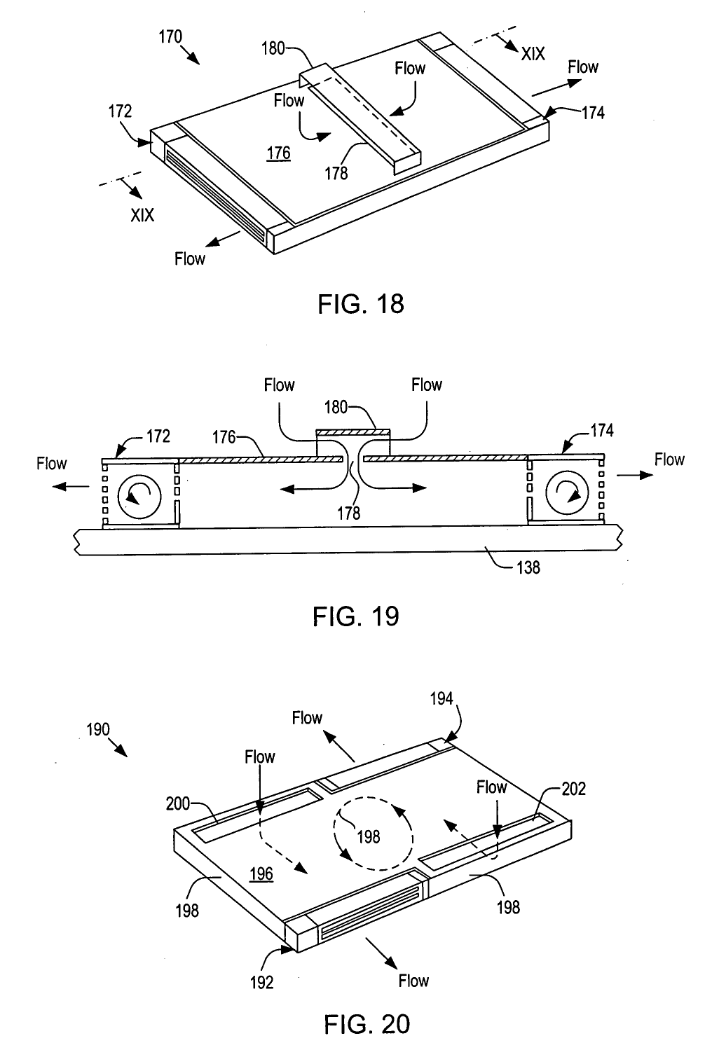

FIG. 18 is a schematic perspective view of another embodiment of a heat sink 170 of the type to be used in a graphic card assembly or the like in accordance with the present invention. FIG. 19 is a schematic cross sectional view of the heat sink 170, taken along the line XIX-XIX. As depicted, the heat sink 170 is similar to the heat sink 160 in FIGS. 16-17, with the differences that the heat sink includes an elongated cover 180 disposed over an elongated opening or slit 178. The cover 180 covers the opening 178 to prevent foreign particles from entering through the opening 178 and/or directly hitting the surface of the graphic card assembly 138 or the like.

It is noted that the fans in FIGS. 12-15 can be arranged to have the outlet ports face away from the channel, i.e., the fans discharge ambient fluid from the channel through the outlet ports. Likewise, the fans in FIGS. 16-19 can be arranged to have the outlet ports face the channel, i.e., the fans direct ambient fluid into the channel toward the openings formed in the upper plate.

FIG. 20 is a schematic perspective view of another embodiment of a heat sink 190 of the type to be used in a graphic card assembly or the like in accordance with the present invention. As depicted, the heat sink includes a fan 192 disposed at the foreground side of the rightmost edge thereof and another fan 194 disposed at the background side of the leftmost edge thereof. In this embodiment, the upper plate (or wall) 196 and four side plates (or walls) 198 form a flow channel. Ambient fluid is drawn into the heat sink through two openings or slits 200, 202 formed in the upper plate 196, while the drawn fluid is discharged from the heat sink by the two fans 192, 194 through the outlet ports of the fans. The fan 192 draws the ambient fluid through the opening 200, while the fan 19=draws the ambient fluid through the opening 202 such that the flow near the foreground side of the heat sink generated by the fan 192 proceeds in a direction opposite to the flow near the background side of the heat sink generated by the fan 194. A portion of the flow near the foreground side is mixed with a portion of the flow near the background side such that a vortex or swirl 198 may be induced at the central portion of the heat sink, enhancing the heat extraction efficiency.

Although the present invention has been described above in terms of a single preferred embodiment, it is understood that various modifications in size, relative dimensions, inlet and outlet configurations, rotor vane configuration, construction methods and materials, etc., will no doubt become apparent to those skilled in the art after having read this disclosure. Accordingly, it is intended that the above disclosure be interpreted as exemplary rather than limiting, and that the appended claims be interpreted broadly, and limited only by the true spirit and scope of the invention.

I claim:

1. A means for removing heat from electronic components, comprising:
a heat sink for attachment to an electronic component, adapted to form at least one flow channel, and including means for directing a stream of heat removing fluid over at least one surface thereof; and
a plurality of fans for attachment to said heat sink, each said fan adapted to generate said stream of heat removing fluid through said channel and including
an elongated housing open along its length and at both ends to form a rotor receiving chamber, said housing having an inlet port formed in one side thereof and an outlet port formed in another side thereof;
an elongated rotor disposed within said chamber and rotatable about a longitudinal axis thereof, said rotor having a plurality of impeller components extending along its length,
a first end cap affixed to said housing and closing one end of said chamber, and a second end cap affixed to said housing and closing an opposite end thereof;
a motor disposed at said one end of said chamber and adapted to cause said rotor to rotate about said longitudinal axis whereby ambient fluid is drawn through said inlet port into said chamber by said impeller components and expelled therefrom through said outlet port; and
means for mounting said fan to said heat sink.

2. A means as recited in claim 1, wherein portions of the downstream end of said channel are positioned substantially normal to each other, said fans including first and second fans respectively disposed on two side walls upstream of said channel, the outlet port of said first fan facing one of said portions, the outlet port of said second fan facing another one of said portions, said first and second fans directing flows toward said portions through said channel.

3. A means as recited in claim 1, wherein said fans are arranged at one end of said channel and said outlet ports of said fans face an opposite end of said channel.

4. A means as recited in claim 3, wherein said fans are arranged in one dimensional array form such that a first end cap of a first fan is in contact with a second end cap of a second fan.

5. A means as recited in claim 3, wherein said fans are arranged in a two dimensional array and wherein, in each row of said two dimensional array, a first end cap of a first fan is in contact with a second end cap of a second fan.

6. A means as recited in claim 1, wherein said fans include a first fan positioned at one end of said channel and a second fan positioned at an opposite end of said channel and wherein the outlet port of said first fan faces the inlet port of said second fan whereby a flow directed into said channel by said first fan proceeds toward said second fan through said channel.

7. A means as recited in claim 1, further comprising:
a middle plate forming an other channel adjacent said one channel,
wherein said fans includes a first fan positioned at one end of said one channel and a second fan positioned at an opposite end of said other channel and wherein a flow generated by said first fan in said one channel proceeds in a direction opposite to a flow generated by said second fan in said other channel.

8. A means as recited in claim 1, wherein said heat sink includes a plate having a portion shaped in an elongated exit port, said fans including a first fan positioned at one end of said channel and a second fan positioned at an opposite end of said channel, said fans being operative to direct ambient fluid into said channel and send the ambient fluid toward said exit port through said channel whereby the ambient fluid is discharged from said channel through said exit port.

9. A means as recited in claim 8, wherein said heat sink further includes a flow deflector disposed within said channel and operative to direct the ambient fluid drawn into said channel toward said exit port.

10. A means as recited in claim 9, wherein said flow deflector is disposed on top of a heat generating component whereby heat energy generated by said heat generating component is transferred through said flow deflector to the ambient fluid drawn into said channel.

11. A means as recited in claim 9, wherein said flow deflector includes a pair of elongated plates attached to the bottom surface of said upper plate and disposed under said exit port and arranged in a spaced-apart relationship with said exit port.

12. A means as recited in claim 1, wherein said heat sink includes a plate having an elongated opening formed therein, said fans including a first fan positioned at one end of said channel and a second fan positioned at an opposite end of said channel, said fans being operative to draw ambient fluid into said channel through said opening and to discharge the ambient fluid from said channel through said outlet ports thereof.

13. A means as recited in claim 12, wherein said heat sink further includes an elongated cover disposed over said opening to cover said opening thereby to prevent foreign particles from entering into said channel through said opening.

14. A means as recited in claim 1, wherein said channel is formed by a top wall and four side walls secured to said top wall, said top wall having two openings formed therein, said fans including first and second fans respectively disposed in first and second ones of the fours side walls and said first and second side walls facing each other, said first opening being positioned such that said first fan is operative to direct ambient fluid into said channel through said first opening and to discharge ambient fluid from said channel through the outlet port thereof thereby to generate a first flow in said channel, said second opening being positioned such that said second fan is operative to direct ambient fluid into said channel through said second opening and to discharge ambient fluid from said channel through the outlet port thereof thereby to generate a second flow in said channel, said first flow proceeding in a direction opposite to said second flow, a portion of said first flow being mixed with a portion of said second flow to induce a vortex at the center of said channel.

15. A means as recited in claim 1, wherein said inlet port includes inlet openings formed in a first wall of said housing, and said outlet port includes outlet openings formed in a second wall of said housing, said first and second walls lying on opposite sides of said longitudinal axis.

16. A means as recited in claim 15, wherein said inlet openings are formed in said first wall of said housing on one side of a first plane normal to said first wall and passing through said longitudinal axis, and wherein said outlet openings are formed in said second wall of said housing and symmetrical about said first plane.

17. A means as recited in claim 1, wherein said elongated housing and said end caps form a right rectangular object of length L, width W and depth D, where W is a dimension substantially equal to D, and L is a dimension substantially larger than the dimensions W and D.

18. A means as recited in claim 1, further comprising:
a plurality of ribs extending along the direction of said stream, each said rib having a shape of an elongated strip.
